(19) United States
(12) Patent Application Publication
(10) Pub. No.: US 2024/0282704 A1
(43) Pub. Date: Aug. 22, 2024

(54) SUBTRACTIVE METAL VIA WITH METAL BRIDGE

(71) Applicant: International Business Machines Corporation, Armonk, NY (US)

(72) Inventors: Yann Mignot, Slingerlands, NY (US); Chanro Park, Clifton Park, NY (US); Koichi Motoyama, Clifton Park, NY (US); John Christopher Arnold, North Chatham, NY (US)

(21) Appl. No.: 18/171,795

(22) Filed: Feb. 21, 2023

(51) Int. Cl. H01L 23/528; H01L 21/768; H01L 23/522; H01L 23/532

(52) U.S. Cl. CPC H01L 23/5283; H01L 21/76802; H01L 21/76883; H01L 21/76885; H01L 23/5226; H01L 23/53257

(57) ABSTRACT

A semiconductor structure is presented including a metal layer having a first pattern, a metal bridge located within the first pattern, at least one via disposed on a portion of the metal layer such that the metal bridge extends to a top surface of the at least one via, and a metal cap disposed directly on top of the at least one via disposed on the portion of the metal layer.

### BACKGROUND

The present invention relates generally to semiconductor devices, and more specifically, to constructing a subtractive metal via with a metal bridge.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a metal layer having a first pattern, a metal bridge located within the first pattern, at least one via disposed on a portion of the metal layer such that the metal bridge extends to a top surface of the at least one via, and a metal cap disposed directly on top of the at least one via disposed on the portion of the metal layer.

In accordance with another embodiment, a semiconductor structure is provided. The semiconductor structure includes a metal layer having a first pattern, a metal bridge directly contacting the metal layer, and a via disposed on a portion of the metal layer such that the metal bridge extends along a sidewall of the via to a topmost surface of the via.

In accordance with yet another embodiment, a method is provided. The methods includes forming a metal layer having a first pattern, constructing a metal bridge located within the first pattern, forming at least one via on a portion of the metal layer such that the metal bridge extends to a top surface of the at least one via, and disposing a metal cap directly on top of the at least one via disposed on the portion of the metal layer.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a litho stack over metal layers, in accordance with an embodiment of the present invention;

FIG. 2 is a cross-sectional view of the semiconductor structure of FIG. 1 where litho patterning takes place to form a first set of a plurality of metal trenches, in accordance with an embodiment of the present invention;

FIG. 3 is a cross-sectional view of the semiconductor structure of FIG. 2 where a cut mask is optionally applied to selectively remove metal trench portions, in accordance with an embodiment of the present invention;

FIG. 4 is a cross-sectional view of the semiconductor structure of FIG. 3 where a trilayer stack is deposited and trenches are selectively formed, in accordance with an embodiment of the present invention;

FIG. 5 is a cross-sectional view of the semiconductor structure of FIG. 4 where the trilayer stack is selectively removed to expose recessed metal layers, in accordance with another embodiment of the present invention;

FIG. 6 is a cross-sectional view of the semiconductor structure of FIG. 5 where a first dielectric is deposited and chemical mechanical polishing (CMP) is performed, in accordance with an embodiment of the present invention;

FIG. 7 is a cross-sectional view of the semiconductor structure of FIG. 6 where another trilayer stack is deposited, in accordance with an embodiment of the present invention;

FIG. 8 is a cross-sectional view of the semiconductor structure of FIG. 7 where the trilayer stack and the first dielectric are selectively etched to form trenches, in accordance with an embodiment of the present invention;

FIG. 9 is a cross-sectional view of the semiconductor structure of FIG. 8 where remaining trilayer portions are removed, in accordance with another embodiment of the present invention;

FIG. 10 is a cross-sectional view of the semiconductor structure of FIG. 9 where a metal fill takes place and CMP is performed, in accordance with an embodiment of the present invention;

FIG. 11 is a cross-sectional view of the semiconductor structure of FIG. 10 where another trilayer stack is deposited, in accordance with an embodiment of the present invention;

FIG. 12 is a cross-sectional view of the semiconductor structure of FIG. 11 where the trilayer stack is removed and at least one of the metals is etched, in accordance with an embodiment of the present invention;

FIG. 13 is a cross-sectional view of the semiconductor structure of FIG. 12 where a second dielectric is deposited and CMP takes place to planarize three metal regions, in accordance with an embodiment of the present invention; and

FIG. 14 is a 3D view and cross-sectional view highlighting the metal bridges, in accordance with an embodiment of the present invention.

Throughout the drawings, same or similar reference numerals represent the same or similar elements.

### DETAILED DESCRIPTION

Embodiments in accordance with the present invention provide methods and devices for constructing metal via multi-levels. The exemplary semiconductor structures includes a metal layer having a first pattern, a metal bridge located within the first pattern, at least one via disposed on a portion of the metal layer such that the metal bridge extends to a top surface of the at least one via, and a metal cap disposed directly on top of the at least one via disposed on the portion of the metal layer. Therefore, the exemplary embodiments define an additional metal for extra level connection. Stated differently, an extra metal block is added after the trench such that a trench plus top via is capable of connecting the trenches together to form a metal island.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

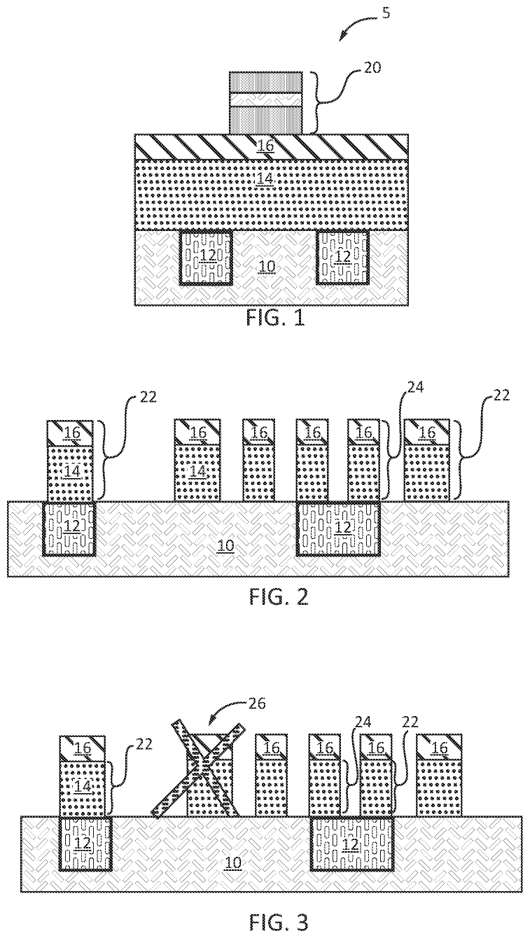

FIG. 1 is a cross-sectional view of a semiconductor structure including a litho stack over metal layers, in accordance with an embodiment of the present invention.

In various example embodiments, structure 5 includes metal lines 12 (M1) formed within a dielectric material 10. In an alternative structure, middle-of-line (MOL) contacts form the metal lines 12 within the dielectric material 10. A bilayer metal is deposited over the metal lines 12. The bilayer metal includes a first metal layer 14 and a second metal layer 16. A litho stack 20 is deposited over the bilayer metal. The first metal layer 14 can be, e.g., ruthenium (Ru). The Ru layer can have a thickness of about 10-50 nm. The second metal layer 16 can be, e.g., titanium nitride (TiN) or tantalum nitride (TaN). The TiN or TaN layer can have a thickness of about 5-10 nm.

The metal lines 12 (M1) represent a first level of interconnect wiring or the last MOL contact level.

Non-limiting examples of suitable conductive materials for the first level of interconnect wiring include a refractory metal liner such as TaN, an adhesion metal liner, such as Co or Ru, and a conductive metal fill, such as Al, W, Cu, Co, Ru, Mo, Ir, etc. The conductive material can further include dopants that are incorporated during or after deposition. The conductive metal can be deposited by a suitable deposition process, for example, CVD, PECVD, PVD, plating, thermal or e-beam evaporation, and sputtering. The only requirement for the first metal layer 14 and the second metal layer 16 is to have enough etch selectivity against each other in the order of greater than 10:1, respectively.

Regarding various dielectrics or dielectric layers discussed herein, the dielectrics can include, but are not limited to, SiN, SiOCN, SiOC, SiC, SiON, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

FIG. 2 is a cross-sectional view of the semiconductor structure of FIG. 1 where litho patterning takes place to form a first set of a plurality of metal trenches, in accordance with an embodiment of the present invention.

In various example embodiments, the bilayer metal is etched to form a set of a plurality of first metal trenches. Some of the first set of the plurality metal trenches 22 have a first width and some of the first set of the plurality of metal trenches 24 have a second width, where the first width is greater than the second width. The etching extends to a top surface of the dielectric material 10. The first set of the plurality of metal trenches 22, 24 have a bilayer metal arrangement.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process. Ruthenium metal is generally etched using O₂with Ar for the physical component and CH₄ as a dilution gas to reduce the polymerization. Other dry etchant gasses can include, chlorine base gases (e.g., Cl₂, BCl₃), Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

FIG. 3 is a cross-sectional view of the semiconductor structure of FIG. 2 where a cut mask is optionally applied to selectively remove metal trench portions, in accordance with an embodiment of the present invention.

In various example embodiments, a cut mask 26 is applied to selectively remove metal trench portions. The removed metal trench portion is crossed out by an “X.” It is noted that this can be an optional step.

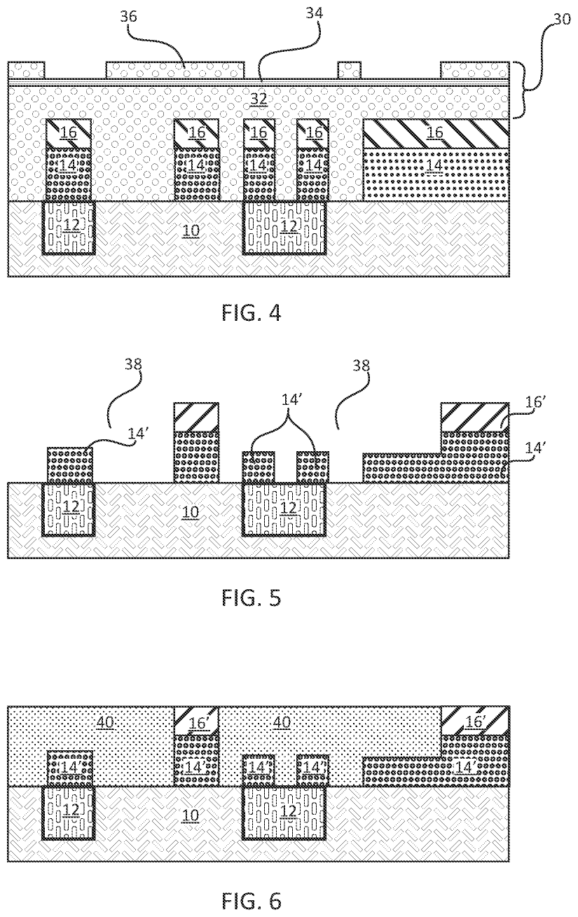

FIG. 4 is a cross-sectional view of the semiconductor structure of FIG. 3 where a trilayer stack is deposited and trenches are selectively formed, in accordance with an embodiment of the present invention.

In various example embodiments, a trilayer stack 30 is deposited and trenches are selectively formed. The trilayer stack 30 includes a first layer 32, a second layer 34, and a third layer or photoresist material 36.

The first layer 32 and the second layer 34 can be employed as a lithographic stack to pattern the underlying layers. The first layer 32 can be, e.g., an organic planarization layer (OPL). The second layer 34 can be, e.g., an anti-reflective (ARC) layer or a low temperature oxide (LTO) layer.

The first layer 32 (or OPL) is formed at a predetermined thickness to provide reflectivity and topography control during etching of the hard mask layers below. The OPL can include an organic material, such as a polymer. The thickness of the OPL can be in a range from about 50 nm to about 300 nm.

The second layer 34 (or ARC layer) minimizes the light reflection during lithography for a lithography stack. The ARC layer can include silicon, for example, a silicon anti-reflective layer (SiARC). The thickness of the ARC layer can be in range from about 10 nm to about 100 nm. The ARC layer can be an antireflective layer for suppressing unintended light reflection during photolithography. Exemplary materials for an ARC layer include, but are not limited to, metal silicon nitrides, or a polymer film. The ARC layer can be formed, depending on materials, for example, using sputter deposition, chemical vapor deposition, or spin coating.

A photolithography process usually includes applying a layer of a photoresist chemically amplified resist (CAR) material (e.g., a material that will react when exposed to light), and then selectively exposing portions of the photoresist material 36 to light or other ionizing radiation (e.g., ultraviolet, electron beams, X-rays, etc.), thereby changing the solubility of portions of the material. The photoresist material 36 is then developed by washing the resist with a developer solution, such as, e.g., tetramethylammonium hydroxide (TMAH), thereby removing non-irradiated (in a negative resist) or irradiated (in a positive resist) portions of the resist layer. Other types of resist can be used like Metal Organics Resist (MOR) containing a small metal fraction such as, for example, tin (═Sn) with subsequent development done by dry clean.

FIG. 5 is a cross-sectional view of the semiconductor structure of FIG. 4 where the trilayer stack is selectively removed to expose recessed metal layers, in accordance with another embodiment of the present invention.

In various example embodiments, the trilayer stack 30 is selectively removed to expose recessed metal layers. Trenches 38 are created between the recessed metal layers. The recessed metal layers are designated as 14′, 16′.

FIG. 6 is a cross-sectional view of the semiconductor structure of FIG. 5 where a first dielectric is deposited and CMP is performed, in accordance with an embodiment of the present invention.

In various example embodiments, a first dielectric 40 is deposited and CMP is performed such that the top surface of the first dielectric 40 is flush with the top surface of the recessed metal layer 16′.

The first dielectric 40 can be, e.g., an oxide.

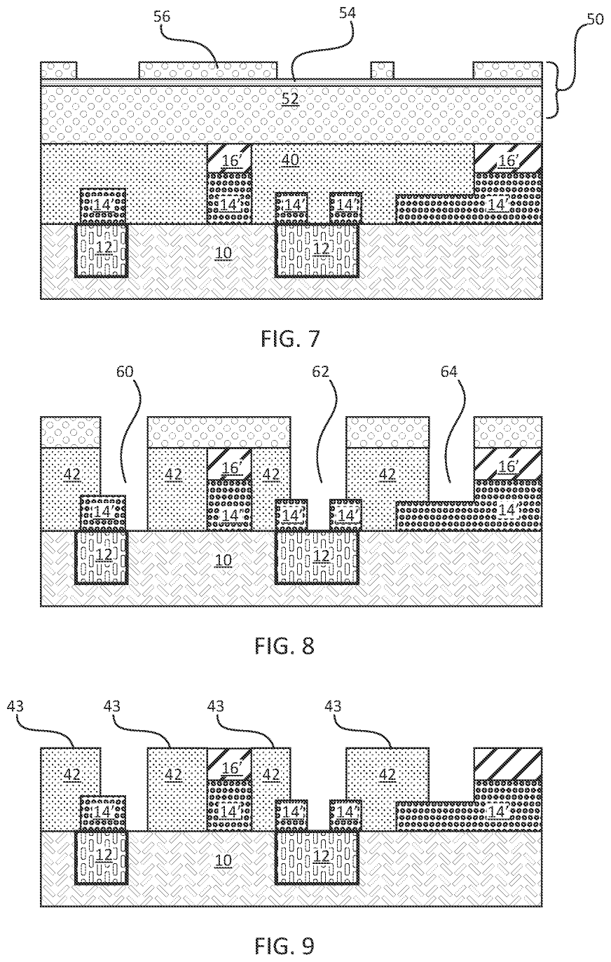

FIG. 7 is a cross-sectional view of the semiconductor structure of FIG. 6 where another trilayer stack is deposited, in accordance with an embodiment of the present invention.

In various example embodiments, another trilayer stack 50 is deposited.

The first layer 52 and the second layer 54 can be employed as a lithographic stack to pattern the underlying layers. The first layer 52 can be, e.g., an organic planarization layer (OPL). The second layer 54 can be, e.g., an anti-reflective (ARC) layer or a low temperature oxide (LTO) layer. The third layer can be, e.g., a photoresist material 56.

FIG. 8 is a cross-sectional view of the semiconductor structure of FIG. 7 where the trilayer stack and the first dielectric are selectively etched to form trenches, in accordance with an embodiment of the present invention.

In various example embodiments, the trilayer stack 50 and the first dielectric 40 are selectively etched to form trenches 60, 62, 64. The trenches 60, 62, 64 expose portions of the recessed metal layer 14′. First dielectric layer portions remain and are referred to as remaining first dielectric layer portions 42.

FIG. 9 is a cross-sectional view of the semiconductor structure of FIG. 8 where remaining trilayer portions are removed, in accordance with another embodiment of the present invention.

In various example embodiments, the remaining trilayer portions are removed, thus exposing the top surface 43 of the remaining first dielectric layer portions 42.

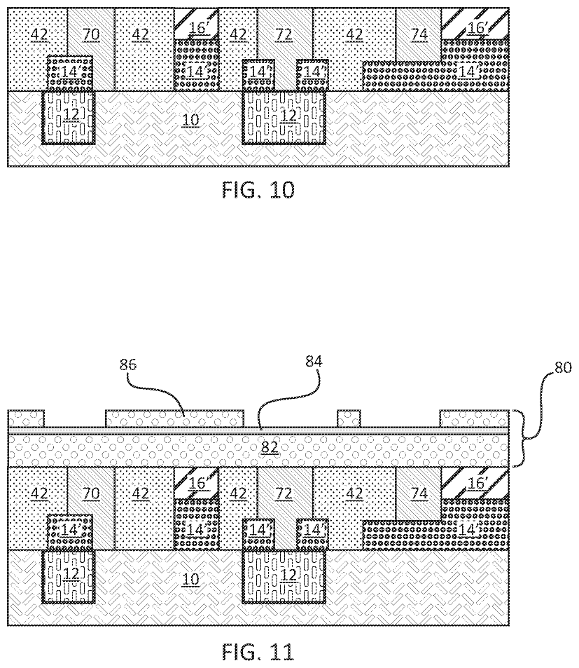

FIG. 10 is a cross-sectional view of the semiconductor structure of FIG. 9 where a metal fill takes place and CMP is performed, in accordance with an embodiment of the present invention.

In various example embodiments, a metal fill takes place. The metal fill results in a first metal region 70, a second metal region 72, and a third metal region 74. The first, second, and third metal regions 70, 72, 74 have different shapes and sizes with respect to each other. CMP also takes place to planarize the first, second, and third metal regions 70, 72, 74. The first, second, and third metal regions 70, 72, 74 are flush with the top surface 43 of the remaining first dielectric layer portions 42.

The first, second, and third metal regions 70, 72, 74 could be non-limiting examples of suitable conductive materials like, e.g., molybdenum, iridium, tungsten, titanium, tantalum, ruthenium, zirconium, cobalt, copper, aluminum, lead, platinum, tin, silver, gold), or any suitable combination of these materials.

FIG. 11 is a cross-sectional view of the semiconductor structure of FIG. 10 where another trilayer stack is deposited, in accordance with an embodiment of the present invention.

In various example embodiments, another trilayer stack 80 is deposited.

The first layer 82 and the second layer 84 can be employed as a lithographic stack to pattern the underlying layers. The first layer 82 can be, e.g., an organic planarization layer (OPL). The second layer 84 can be, e.g., an anti-reflective (ARC) layer or a low temperature oxide (LTO) layer. The third layer can be, e.g., a photoresist material 86.

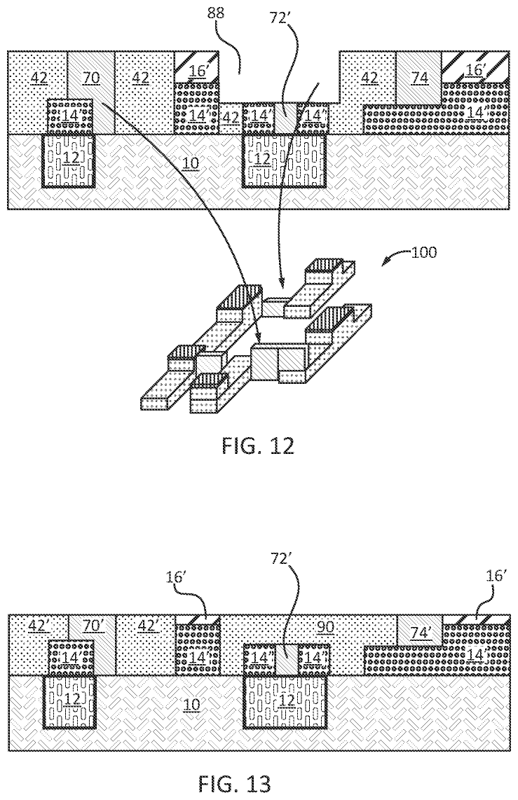

FIG. 12 is a cross-sectional view of the semiconductor structure of FIG. 11 where the trilayer stack is removed and at least one of the metals is etched, in accordance with an embodiment of the present invention.

In various example embodiments, the trilayer stack 80 is removed and at least one of the metals is etched. The removal of the trilayer stack 80 renders opening 88 where the second metal region 72 is etched to form recessed second metal region 72′. The recessed second metal region 72′ is confined between the recessed metal layers 14′.

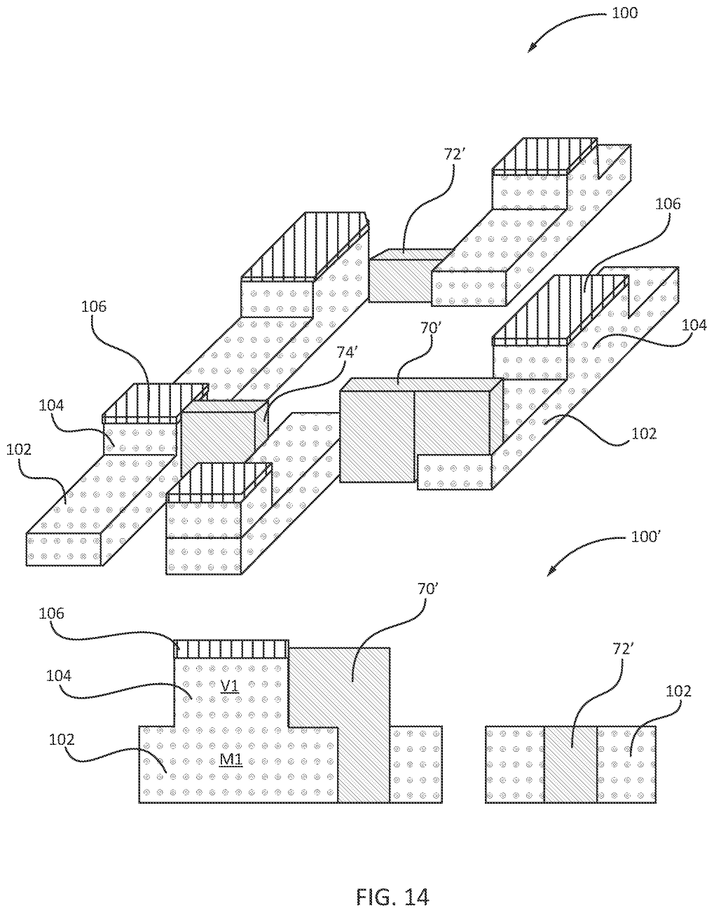

The 3D view 100 of the structure is also illustrated, and will be described in more detail below with reference to FIG. 14.

FIG. 13 is a cross-sectional view of the semiconductor structure of FIG. 12 where a second dielectric is deposited and CMP takes place to planarize three recessed metal regions, in accordance with an embodiment of the present invention.

In various example embodiments, a second dielectric 90 is deposited and CMP takes place to planarize the three metal recessed regions, as well as the second dielectric 90. Thus, a first recessed metal region 70′, the recessed second metal region 72′, and a third recessed metal region 74′ are formed. The first recessed metal region 70′, the recessed second metal region 72′, and the third recessed metal region 74′ are flush with a top surface of the second dielectric 90.

The first recessed metal region 70′, the recessed second metal region 72′, and the third recessed metal region 74′ can be referred to as metal bridges. The metal bridges could be non-limiting examples of suitable conductive materials like, e.g., molybdenum, iridium, tungsten, titanium, tantalum, ruthenium, zirconium, cobalt, copper, aluminum, lead, platinum, tin, silver, gold), or any suitable combination of these materials.

FIG. 14 is a 3D view and cross-sectional view highlighting the metal bridges, in accordance with an embodiment of the present invention.

In various example embodiments, structure 100 is a 3D representation that illustrates an M1layer 102, a via 104 (V1), and a metal cap 106. Structure 100′ illustrates the cross-sectional view depicting the M1layer 102 and the via 104 (V1). Metal bridges are illustrated in structure 100′. The first recessed metal region 70′ can be referred to as a metal bridge and the third recessed metal region 72′ can be referred to as a metal bridge. The metal bridge is at a same level as the metal layer or M1layer 102. The metal bridge is at a same level as the at least one via or via 104 (V1). The metal bridge connects adjoining metal layers. The metal bridge includes a plurality of metals bridges. The plurality of metal bridges are generally rectangular-shaped. It is noted that the empty space is filled with a dielectric (not shown). Such dielectric encompasses or surrounds the metal bridges.

In semiconductor design technology, many metal layers are employed to implement interconnections throughout an integrated circuit. For some integrated circuits, one or more polysilicon (poly) layers, or even active areas, are also used to implement interconnections. Vias are employed to connect from one such metal or polysilicon layer to another metal or polysilicon layer. For example, a via can be used to connect a feature (e.g., a design geometry) on each of two metal layers. The lower one of the two layers is referred to as the landing metal layer and the upper one of the two layers is referred to as the covering layer. A via between a landing metal layer mtₓ and the covering metal layer mtₓ₊₁ is usually referred to as a vₓ via (e.g., using the same subscript designation as the landing metal layer). Embodiments in accordance with the present invention provide methods and devices for constructing metal bridges electrically connecting metal layers and vias where an additional metal for extra level connection is defined.

In conclusion, the exemplary embodiments of the present invention present a metal layer having a first pattern, a metal bridge located within the first pattern, at least one via disposed on a portion of the metal layer such that the metal bridge extends to a top surface of the at least one via, and a metal cap disposed directly on top of the at least one via disposed on the portion of the metal layer. In another embodiment, a metal layer having a first pattern, a metal bridge directly contacting the metal layer, and a via disposed on a portion of the metal layer such that the metal bridge extends along a sidewall of the via to a topmost surface of the via. In yet another embodiment, a method is provided for forming a metal layer having a first pattern, constructing a metal bridge located within the first pattern, forming at least one via on a portion of the metal layer such that the metal bridge extends to a top surface of the at least one via, and disposing a metal cap directly on top of the at least one via disposed on the portion of the metal layer. Therefore, the exemplary embodiments define an additional metal for extra level connection. Stated differently, an extra metal block is added after the trench such that a trench plus top via is capable of connecting the trenches together to form a metal island.

Regarding FIGS. 1-14, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography and EUV techniques.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing a subtractive metal via with a metal bridge (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a metal layer having a first pattern;
a metal bridge located within the first pattern;
at least one via disposed on a portion of the metal layer such that the metal bridge extends to a top surface of the at least one via; and
a metal cap disposed directly on top of the at least one via disposed on the portion of the metal layer.

2. The semiconductor structure of claim 1, wherein the metal bridge is at a same level as the metal layer.

3. The semiconductor structure of claim 1, wherein the metal bridge is at a same level as the at least one via.

4. The semiconductor structure of claim 1, wherein the metal bridge connects adjoining metal layers.

5. The semiconductor structure of claim 1, wherein the metal bridge includes a plurality of metals bridges.

6. The semiconductor structure of claim 5, wherein the plurality of metal bridges are generally rectangular-shaped.

7. The semiconductor structure of claim 1, wherein a dielectric encompasses the metal bridge.

8. The semiconductor structure of claim 1, wherein the metal bridge includes ruthenium (Ru).

9. A semiconductor structure comprising:
a metal layer having a first pattern;
a metal bridge directly contacting the metal layer; and
a via disposed on a portion of the metal layer such that the metal bridge extends along a sidewall of the via to a topmost surface of the via.

10. The semiconductor structure of claim 9, wherein a metal cap is disposed directly on the via disposed on the portion of the metal layer.

11. The semiconductor structure of claim 9, wherein the metal bridge is at a same level as the metal layer.

12. The semiconductor structure of claim 9, wherein the metal bridge is at a same level as the via.

13. The semiconductor structure of claim 9, wherein the metal bridge connects adjoining metal layers.

14. The semiconductor structure of claim 9, wherein the metal bridge includes a plurality of metals bridges.

15. The semiconductor structure of claim 14, wherein the plurality of metal bridges are generally rectangular-shaped.

16. The semiconductor structure of claim 9, wherein a dielectric encompasses the metal bridge.

17. The semiconductor structure of claim 9, wherein the metal bridge includes ruthenium (Ru).

18. A method for constructing a semiconductor structure, the method comprising:
forming a metal layer having a first pattern;
constructing a metal bridge located within the first pattern;
forming at least one via on a portion of the metal layer such that the metal bridge extends to a top surface of the at least one via; and
disposing a metal cap directly on top of the at least one via disposed on the portion of the metal layer.

19. The method of claim 18, wherein the metal bridge is at a same level as the metal layer.

20. The method of claim 18, wherein the metal bridge includes a plurality of metal bridges electrically connecting a plurality of adjoining metal layers.
